(19) United States
(12) Patent Application Publication
(10) Pub. No.: US 2006/0144293 A1
(43) Pub. Date: Jul. 6, 2006

(54) Coating solutions for use in forming bismuth-based ferroelectric thin films and a method of forming bismuth-based ferroelectric thin films using the coating solutions

(76) Inventors: Yoshimi Sato, Kanagawa-ken (JP); Atsushi Kawakami, Kanagawa-ken (JP); Yoshiyuki Takeuchi, Kanagawa-ken (JP)

Correspondence Address: WENDEROTH, LIND & PONACK, L.L.P., 2033 K STREET N. W., SUITE 800, WASHINGTON, DC, 20006-1021, US

(21) Appl. No.: 11/368,482

(22) Filed: Mar. 7, 2006

Related U.S. Application Data
(63) Continuation of application No. 11/042,135, filed on Jan. 26, 2005, now abandoned.
Application No. 11/042,135 is a continuation of application No. 10/665,143, filed on Sep. 22, 2003, now abandoned.
Application No. 10/665,143 is a continuation of application No. 09/793,490, filed on Feb. 27, 2001, now abandoned.

(30) Foreign Application Priority Data
Feb. 28, 2000 (JP) 50889/2000

(51) Int. Cl. B05D 5/12; C23C 16/40; H01L 21/316

(52) U.S. Cl. 106/287.18; 106/287.19; 427/100; 427/126.3

(57) ABSTRACT

Disclosed herein is a coating solution for use in forming Bi-based ferroelectric thin films comprises a specified compound, such as triglyme, dipivaloylmethane, pinacol, pivalic acid or hexyleneglycol, in combination with an organometallic compound containing metallic elements of which a Bi-based ferroelectric thin film to be formed is composed. Disclosed also herein is a method of forming Bi-based ferroelectric thin films using the coating solution.

### BACKGROUND OF THE INVENTION

1. Field of the Invention

This invention relates to coating solutions for use in forming Bi-based ferroelectric thin films and a method of forming bismuth-based ferroelectric thin films using such coating solutions. The invention is particularly suitable for application to nonvolatile ferroelectric memories and the like.

2. Description of Related Art

Thin films of bismuth layer-structured ferroelectrics (BLSF) represented by the general formula (Bi₂O₂)²⁺(Aₘ₋₁BₘO₃ₘ₊₁)₂ where A is a mono-, di- or trivalent ion (as of Bi, Pb, Ba, Sr, Ca, Na, K or a rare earth element) or combinations of these ions; B is a tetra-, penta- or hexavalent ion (as of a metallic element like Ti, Nb, Ta, W, Mo, Fe, Co or Cr) or combinations of these ions; and m is an integer of 1-51 have recently been found to feature good characteristics such as requiring small remanent polarization (Pr)-coercive field (Ec) hysteresis curves, i.e., P-E hysteresis curves, and hence experiencing less fatigue as a result of repeated polarization switching. This has spotlighted the potential use of BLSF thin films as materials for the fabrication of semiconductor memories and sensors (T. Takenaka, “Bismuth Layer-Structured Ferroelectrics and Their Grain Orientation” in Report of the Workshop on Applied Electronics Properties, The Japan Society of Applied Physics, pp. 1-8, Nov. 22, 1994; and “Ceramics”, Vol. 30, No. 6, pp. 499-503, 1995). Bismuth-based ferroelectric thin films that have attracted particular attention as materials that exhibit those characteristics in a salient manner and which are the subject of active research today include an SBTO type in which Sr is used as metallic element A, and Ta as metallic element B; an SBNO type in which Sr is used as metallic element A, and Nb as metallic element B; an SBTNO type in which Sr is used as metallic element A, and Ta and Nb as metallic element B; and a BLTO type in which La is used as metallic element A, and Ti as metallic element B.

Bismuth-based ferroelectric thin films can be formed by various methods including sputtering, CVD, and by-applying-a-coating film formation. However, due to the great number of oxide components of metallic elements that have to be incorporated as film constituents, sputtering and CVD techniques require costly apparatus, and considerable difficulties are involved in controlling the compositions of ferroelectric thin films at desired levels; hence, these techniques are not suitable for practical applications, particularly on large-diameter substrates. In contrast, the by-applying-a-coating film formation technique does not need expensive apparatus and can deposit films at comparatively low cost; in addition, it provides ease in controlling the compositions of ferroelectric thin films at desired levels.

Therefore, the by-applying-a-coating film formation process holds much promise for commercial use in the formation of Bi-based ferroelectric thin films.

For coating solutions used in the by-applying-a-coating film formation technique for forming Bi-based ferroelectric thin films, organic coating solutions dissolving organometallic compounds in organic solvents are known, where the organometallic compounds may exemplified as salts of carboxylic acids having a medium-chain hydrocarbon group such as 2-ethylhexanoic acid and constituent metallic elements in the thin films, and metal alkoxide compounds comprising alcohols such as ethanol, methoxyethanol or methoxypropanol and constituent metallic elements in the thin films, and the like.

In particular, coating solutions containing metal alkoxide compounds are drawing increasing attention since by compositing or hydrolyzing the metal alkoxide compounds, the relative proportions of metals in the solution can be stabilized so that the loss of highly-sublimable metals (e.g., Bi) by burning during film formation is effectively suppressed to prevent a change in the relative contents of metals in the product film (see, for example, Unexamined Published Japanese Patent Application (kokai) Nos. 258252/1998 and 259007/1998).

It is generally understood that if devices such as Bi-based ferroelectric memories suffering less fatigue and exhibiting good electrical characteristics are to be fabricated using Bi-based ferroelectric thin films, the films have to be crystallized by heating them at an elevated temperature of about 800° C. for a prolonged time of about 30-120 minutes. However, the prolonged heat treatment at elevated temperature has the disadvantage of increasing the chance of causing thermal damage to IC circuits and substrates. As the efforts to increase the packing density and, hence, the degree of integration of semiconductor apparatus are being made today at an ever increasing pace, it has become more necessary than before to fabricate ferroelectric devices as components of the semiconductor apparatus by a process that suffers the least from adverse effects such as thermal damage due to heat treatments. To this end, it is necessary to develop coating solutions that provide films that can be crystallized at low temperature or by brief heating.

In particular, coating solutions that permit crystallization by brief heating are desirable from the viewpoint of higher throughput and it is desired to develop coating solutions that are adapted to rapid heat treatments commonly called RTA (rapid thermal annealing) or RTP (rapid thermal processing). Since Bi-based ferroelectric thin films are inorganic metal oxide films, coating solutions adapted to RTA are desirably such that the organic components in the solution have low enough decomposition temperature to permit rapid conversion of the applied film to inorganic nature. In addition, in order to prevent the formation of a cracked or porous film, the desired coating solutions are such that the applied coat should lose only small weight after decomposition of the organic components.

### SUMMARY OF THE INVENTION

An object, therefore, of the present invention is to provide a coating solution for use in forming Bi-based ferroelectric thin films that may include one or more of the advantages of permitting organic components to be decomposed at low enough temperature, forming a coat that permits rapid conversion to inorganic nature, and forming a coat that loses only small weight after decomposition of organic components.

Another object of the invention is to provide a method of forming Bi-based ferroelectric thin films using the coating solution.

As a result of the intensive studies made in order to attain the stated objects, the present inventors found that those objects could be attained by incorporating specified compound(s) such as triglyme, dipivaloylmethane, pinacol, pivalic acid or hexyleneglycol in coating solutions for use in forming Bi-based ferroelectric thin films that contained organometallic compounds. The present invention has been accomplished on the basis of this finding.

Thus, in its first aspect, the present invention relates to a coating solution for use in forming Bi-based ferroelectric thin films that comprises an organometallic compound containing the metallic elements of which a Bi-based ferroelectric thin film is composed and a compound represented by the following general formula (I):
H₃CO—(C₂H₄O)ₙ—CH₃ (I)
where n is an integer of 2-5.

The present invention also relates to a coating solution for use in forming Bi-based ferroelectric thin films that comprises an organometallic compound containing the metallic elements of which a Bi-based ferroelectric thin film is composed, and a compound represented by the following general formula (II):
(R¹)₃C—CO—CH₂—CO—C(R¹)₃ (II)
where R¹ is an alkyl group having 1-3 carbon atoms.

The present invention also relates to a coating solution for use in forming Bi-based ferroelectric thin films that comprises an organometallic compound containing the metallic elements of which a Bi-based ferroelectric thin film is composed, and a compound represented by the following general formula (III):
(R¹)₂C(OH)—C(OH)(R¹)₂ (III)
where R¹ is an alkyl group having 1-3 carbon atoms.

The present invention also relates to a coating solution for use in forming Bi-based ferroelectric thin films that comprises an organometallic compound containing the metallic elements of which a Bi-based ferroelectric thin film is composed, and a compound represented by the following general formula (IV):
(R¹)₃C—COOH (IV)
where R¹ is an alkyl group having 1-3 carbon atoms.

The present invention also relates to a coating solution for use in forming Bi-based ferroelectric thin films that comprises an organometallic compound containing the metallic elements of which a Bi-based ferroelectric thin film is composed, and a compound represented by the following general formula (V):
(R¹)₂C(OH)—CH₂—CH(OH)R¹ (V)
where R¹ is an alkyl group having 1-3 carbon atoms.

In its second aspect, the present invention relates to a method of forming Bi-based ferroelectric thin films which comprises applying one of the coating solutions described above onto a substrate, drying the applied coating solution, and then performing a rapid heat treatment at a temperature rise rate of at least 10° C./s to form a Bi-based ferroelectric thin film.

### BRIEF DESCRIPTION OF THE DRAWINGS

FIG. 1 is a graph showing the TG curve for coating solution 1 prepared in Synthesis 1;

FIG. 2 is a graph showing the TG curve for coating solution 2 prepared in Synthesis 2;

FIG. 3 is a graph showing the TG curve for coating solution 3 prepared in Synthesis 3;

FIG. 4 is a graph showing the TG curve for coating solution 4 prepared in Synthesis 4;

FIG. 5 is a graph showing the TG curve for coating solution 5 prepared in Synthesis 5;

FIG. 6 is a graph showing the TG curve for coating solution 6 prepared in Synthesis 6;

FIG. 7 is a graph showing the TG curve for coating solution 7 prepared in Synthesis 7;

FIG. 8 is a graph showing the TG curve for coating solution 8 prepared in Synthesis 8;

FIG. 9 is a graph showing the TG curve for coating solution 9 prepared in Synthesis 9;

FIG. 10 is a graph showing the TG curve for coating solution 10 prepared in Synthesis 10;

FIG. 11 is a graph showing the TG curve for coating solution 11 prepared in Synthesis 11;

FIG. 12 is a graph showing the TG curve for comparative coating solution 1 prepared in Comparative Synthesis 1;

FIG. 13 is a graph showing the TG curve for comparative coating solution 2 prepared in Comparative Synthesis 2;

FIG. 14 is a graph showing the TG curve for comparative coating solution 3 prepared in Comparative Synthesis 3;

FIG. 15 is a graph showing the TG curve for comparative coating solution 4 prepared in Comparative Synthesis 4;

FIG. 16 is a graph showing the TG curve for comparative coating solution 5 prepared in Comparative Synthesis 5;

FIG. 17 is a graph showing the TG curve for comparative coating solution 6 prepared in Comparative Synthesis 6;

FIG. 18 is a graph showing the XRD curve for coating solution 1;

FIG. 19 is a graph showing the XRD curve for coating solution 2;

FIG. 20 is a graph showing the XRD curve for coating solution 3;

FIG. 21 is a graph showing the XRD curve for coating solution 5;

FIG. 22 is a graph showing the XRD curve for coating solution 9;

FIG. 23 is a graph showing the XRD curve for comparative coating solution 1;

FIG. 24 is a scanning electron micrograph (SEM) of the ferroelectric thin film formed with coating solution 1; and

FIG. 25 is a SEM of the ferroelectric thin film formed with comparative coating solution 1.

### DETAILED DESCRIPTION OF THE INVENTION

The present invention is now described in detail.

The coating solution of the invention for use in forming Bi-based ferroelectric thin films comprises an organometallic compound containing the metallic elements of which a Bi-based ferroelectric thin film is composed, and at least any one of the compounds represented by the general formulae (I)-(V) set forth below.

The coating solutions of the invention for use in forming Bi-based ferroelectric thin films are preferably those intended to form thin films containing Bi-layered structure compounds represented by the following general formula (VI):
(Bi₂O₂)²(Aₘ₋₁BₘO₃ₘ₊₁)² (VI)
where A is at least one metallic element selected from among Bi, Pb, Ba, Sr, Ca, Na, K and a rare earth metallic element; B is at least one metallic element selected from among Ti, Nb, Ta, W, Mo, Fe, Co and Cr; and m is an integer of 1-5.

More preferred are coating solutions intended to form thin films containing Bi-layered structure compounds represented by the following general formula (VII):
Sr₁₋ₓBi_{2+y}(Ta_{2-z},Nb_{z})O_{9+α} (VII):
where 0≦x, y and α, independently <1; and 0≦z<2.

Also preferred are coating solutions intended to form thin films containing Bi-layered structure compounds represented by the following general formula (VIII):
La₁₋ₓBi_{4-y}Ti₃O_{12+α} (VIII)
where 0≦x, y and α, independently <1.

Examples of the organometallic compounds, that are contained in the coating solutions of the invention, and which contain the metallic elements of which the Bi-based ferroelectric thin films are composed, include salts of carboxylic acids having a medium-chain hydrocarbon group such as 2-ethylhexanoic acid and the constituent metallic elements in the thin films, as well as metal alkoxide compounds comprising alcohols such as ethanol, methoxyethanol or methoxypropanol and the constituent metallic elements in the thin films. In the present invention, metal alkoxide compounds having at least one alkoxyl group bonded are preferably used since they enter more easily into reaction with the compounds of the general formulae (I)-(V) set forth below by means of mechanism such as alkoxide exchange.

Preferred metal alkoxide compounds are those which contain a Bi alkoxide, a metal A alkoxide, where A is at least one metallic element selected from among Bi, Pb, Ba, Sr, Ca, Na, K and a rare earth metallic element, and a metal B alkoxide, where B is at least one metallic element selected from among Ti, Nb, Ta, W, Mo, Fe, Co and Cr.

These metal alkoxide compounds may have two or more dissimilar non-alkoxyl groups, such as carboxyl groups, attached to the constituent metallic elements.

In a particularly preferred case of the invention, at least two dissimilar metal alkoxides selected from among the metal A alkoxide, metal B alkoxide and Bi alkoxide form a composite metal alkoxide. By compositing two or more dissimilar metal alkoxides, the precipitation (segregation) and burning-away of individual metallic elements and thereby, the generation of leak currents can be effectively suppressed.

The manner in which the metal alkoxides are contained in the coating solutions of the invention may be exemplified by the following specific examples (a)-(e):

(a) A-Bi composite metal alkoxide and metal B alkoxide;

(b) Bi—B composite metal alkoxide and metal A alkoxide;

(c) A-B composite metal alkoxide and Bi alkoxide;

(d) A-Bi—B composite metal alkoxide; and

(e) metal A alkoxide, metal B alkoxide and Bi alkoxide.

The “composite metal alkoxide” as used in the invention means a compound obtainable by reacting dissimilar metal alkoxides in a solvent at a temperature within a range of 20-100° C. for about 2-15 hours. As the reaction progresses, the liquid gradually changes color and eventually turns brown; hence, the completion of this color change in the liquid may safely regarded as the end point of the reaction. The thus obtained composite metal alkoxides are considered to correspond to the ones defined in “Manufacturing Method of Glass Ceramics by Sol-Gel Process and Applications” (Applied Tech. Pub. Co., Jun. 4, 1989), pp. 46-47, and may specifically be represented by ABi(OR²)ₖ(OR³)₃, BBi(OR⁴)ₙ(OR³)₃, AB(OR²)ₖ(OR⁴)ₙ and ABBi(OR²)ₖ(OR⁴)ₙ(OR³)₃, where A and B are as defined above; k is the valence of metallic element A; n is the valence of metallic element B; and R², R³ and R⁴ each independently represent an alkyl group having 1-6 carbon atoms. Among these, ABi(OR²)ₖ(OR³)₃, BBi(OR⁴)ₙ(OR³)₃ and ABBi(OR²)ₖ(OR⁴)ₙ(OR³)₃, which contain highly-sublimable Bi, are preferably used and they correspond to above-mentioned cases (a), (b) and (d).

Alcohols that are preferably used to form the metal alkoxides and composite metal alkoxides are represented by the following general formula (IX):
R⁵OH (IX)
where R⁵ is a saturated or unsaturated hydrocarbon group having 1-6 carbon atoms. Specific examples of such alcohols include methanol, ethanol, propanol, butanol, amyl alcohol and cyclohexanol.

Apart from these, alcohols in which R⁵ is substituted by alkoxyl groups of 1-6 carbon atoms may also be used and specific examples include methoxymethanol, methoxyethanol, ethoxymethanol, ethoxyethanol, methoxypropanol and ethoxypropanol.

In addition to the above-described organometallic compounds, the coating solution of the invention incorporates any one of the compounds represented by the following general formulae (I)-(V), and which are hereunder sometimes referred to as “specified compounds”:
H₃CO—(C₂H₄O)ₙ—CH₃ (I)
(R¹)₃C—CO—CH₂—CO—C(R¹)₃ (II)
(R¹)₂C(OH)—C(OH)(R¹)₂ (III)
(R¹)ₙC—COOH (IV)
(R¹)₂C(OH)—CH₂—CH(OH)R¹ (V)
where R¹ is an alkyl group having 1-3 carbon atoms; and n is an integer of 2-5.

Among these specified compounds, examples of the compounds represented by the general formula (I) include triglyme and tetraglyme. Tetraglyme is preferred since it has a very low decomposition temperature and exhibits good decomposition characteristics.

A particularly preferred example of the compounds represented by the general formula (II) is dipivaloylmethane since it has good decomposition characteristics.

A particularly preferred example of the compounds represented by the general formula (III) is pinacol since it has good decomposition characteristics.

A particularly preferred example of the compounds represented by the general formula (IV) is pivalic acid since it can easily form an adduct and has good decomposition characteristics. The compounds represented by the general formula (IV) may form acid anhydrides.

A particularly preferred example of the compounds represented by the general formula (V) is 2-methyl-2,4-pentanediol (i.e., hexylene glycol) since it has good decomposition characteristics.

In the coating solutions of the invention, the specified compounds and the organometallic compounds are preferably contained in the form of their reaction products in view of the very high efficiency in removing the organic components by decomposition and the small weight loss that occurs after decomposition.

Such reaction products may typically be synthesized by first adding one or more of the organometallic compounds into an organic solvent, then adding one or more of the specified compounds and heating the mixture under a temperature condition of about 10-80° C. for about 0.5-10 hours. However, the reaction conditions are not limited to these temperature and time ranges, etc.

The coating solutions of the invention can be produced by adding the thus synthesized products of reaction between the organometallic compounds and the specified compounds to an organic solvent and mixing the ingredients. Alternatively, the coating solutions can be produced by first adding the necessary organometallic compounds into an organic solvent and mixing them to form a mixture solution, to which the necessary specific compounds are added and subjected to a heat treatment under a temperature condition of about 10-80° C. for about 0.5-3 hours, preferably under a temperature condition of about 50-60° C. for about 1.5-2.5 hours. The methods of preparing the coating solutions of the invention are in no way limited to these examples.

The specified compounds are preferably used in amounts (in moles) that satisfy the following Equation 1 with respect to the total valence of the metallic elements in stoichiometric proportions in the coating solution (which is hereunder referred to simply as the “total valence”):
[Total valence]/30≦amount of use (in moles) <Equation 1>

A particularly preferred range is [total valence]/6≦amount of use (in moles)≦[total valence]/2. If the specified compound is used in amounts (in moles) less than [total valence]/30, the decomposition temperatures of the organic components will not be adequately lowered. There is no particular limitation on the maximum amount for the use of the specified compounds. However, if they are added in excessive amounts, the coating characteristics of the coating solution may sometimes deteriorate or the denseness of the coating to be finally formed may be affected. Considering this possibility, the specified compounds are preferably used in moles no greater than [total valence]/2.

The total valence under consideration is represented by the following Equation 2:
{[the valence of metal A×the number of moles of metal A compound]+[the valence of Bi×the number of moles of Bi compound]+[the valence of metal B×the number of moles of metal B]}=total valence <Equation 2>

Take, for example, a stoichiometric coating solution of containing 1 mole of Sr compound, 2 moles of Bi compound and 2 moles of Ta compound; Equation 2 is rewritten as {[2 (valence of Sr)×1 (in moles)]+[3 (valence of Bi)×2 (in moles)]+[5 (valence of Ta)×2 (in moles)]}=18 (total valence); in the case of a stoichiometric coating solution of containing 0.75 moles of La compound, 3.25 moles of Bi compound and 3.0 moles of Ti compound, relation 2 is rewritten as {[3 (valence of La)×0.75 (in moles)]+[3 (valence of Bi)×3.25 (in moles)]+[4 (valence of Ti)×3 (in moles)]}=24 (total valence).

Solvents that can be used with the coating solutions for use in forming Bi-based ferroelectric thin films include saturated fatty acids, aromatics, alcohols, glycols, ethers, ketones and esters. Among these, alcohols, glycols, ethers, ketones and esters that have oxygen atoms in the molecule are used with advantage when preparing hydrolyzed sol-gel fluids.

Exemplary alcoholic solvents include methanol, ethanol, propanol, butanol, amyl alcohol, cyclohexanol and methyl cyclohexanol.

Exemplary glycolic solvents include ethylene glycol monomethyl ether, ethylene glycol monoacetate, diethylene glycol monomethyl ether, diethylene glycol monoacetate, propylene glycol monomethyl ether, propylene glycol monoethyl ether, propylene glycol monoacetate, propylene glycol diethyl ether, propylene glycol dipropyl ether, dipropylene glycol monoethyl ether, 3-methoxy-1-butanol, 3-methoxy-3-methylbutanol and 3,3′-dimethylbutanol.

Exemplary ether based solvents include methylal, diethyl ether, dipropylether, dibutyl ether, diamyl ether, diethyl acetal, dihexyl ether, trioxane and dioxane.

Exemplary ketone based solvents include acetone, methyl ethyl ketone, methyl propyl ketone, methyl isobutyl ketone, methyl amyl ketone, methyl cyclohexyl ketone, diethyl ketone, ethyl butyl ketone, trimethyl nonanone, acetonitrile acetone, dimethyl oxide, phorone, cyclohexanone and diacetone alcohol.

Exemplary ester based solvents include ethyl formate, methyl acetate, ethyl acetate, butyl acetate, cyclohexyl acetate, methyl propionate, ethyl butyrate, ethyl oxoisobutyrate, ethyl acetoacetate, ethyl lactate, methoxybutyl acetate, diethyl oxalate, diethyl malonate, triethyl citrate and tributyl citrate.

The solvents listed above may be used either singly or in admixture.

If desired, the above-described coating solutions for use in forming Bi-based ferroelectric thin films may be converted to a sol-gel fluid by hydrolysis and partial polycondensation using water either alone or in combination with a catalyst and this sol-gel fluid is also preferably used.

The coating solutions for use in forming Bi-based ferroelectric thin films may be stabilized with stabilizers such as carboxylic anhydrides, dicarboxylic acid monoesters, β-diketones and glycols and they can also be used with preference.

If desired, the hydrolysis and partial polycondensation treatment may be combined with the stabilizing treatment.

Thus, the following are four specific examples of the preferred mode of the invention: (i) converting the coating solution into a sol-gel fluid by hydrolysis and partial polycondensation with water, either alone or in combination with a catalyst; (ii) converting the coating solution into a gel-sol fluid by hydrolysis and partial polycondensation with water, either alone or in combination with a catalyst and stabilizing it by an added stabilizer; (iii) stabilizing the coating solution; or (iv) stabilizing the coating solution and converting it into a sol-gel fluid by hydrolysis and partial polycondensation with water, either alone or in combination with a catalyst.

The stabilizers listed above are used to improve the storage stability of the coating solutions, particularly by suppressing them from thickening to gel after hydrolysis.

Regarding carboxylic anhydrides as the stabilizer, at least one compound is preferably used as selected from among the carboxylic anhydrides represented by the following general formula (X):
R⁶(CO)₂O (X)
where R⁶ is a divalent saturated or unsaturated hydrocarbon group having 1-6 carbon atoms.

Specific examples of the carboxylic anhydrides include maleic anhydride, citraconic anhydride, itaconic anhydride, succinic anhydride, methylsuccinic anhydride, glutaric anhydride, α-methylglutaric anhydride, α,α-dimethylglutaric anhydride and trimethylsuccinic anhydride.

Regarding dicarboxylic acid monoesters as the stabilizer, at least one compound is preferably used as selected from among the dicarboxylic acid monoesters represented by the following general formula (XI):
R⁷OCOR⁸COOH (XI)
where R⁷ is a saturated or unsaturated hydrocarbon group having 1-6 carbon atoms; and R⁸ is a divalent saturated or unsaturated hydrocarbon group having 1-6 carbon atoms.

Such dicarboxylic acid monoesters may be half esters prepared by reacting dibasic carboxylic acids with alcohols. Specific examples of dibasic carboxylic acids are oxalic acid, malonic acid, succinic acid, glutaric acid, adipic acid, pimelic acid, suberic acid, azelaic acid, sebacic acid, maleic acid, citraconic acid, itaconic acid, methylsuccinic acid, α-methylglutaric acid, α,α-dimethylglutaric acid and trimethylglutaric acid; at least one of these dibasic carboxylic acids may be esterified with at least one alcohol as selected from among methyl alcohol, ethyl alcohol, propyl alcohol, butyl alcohol, amyl alcohol, hexyl alcohol, ethylene glycol monomethyl ether, propylene glycol monomethyl ether, etc. by known methods.

Regarding β-diketones as the stabilizer, at least one compound is preferably used as selected from among the β-diketones including β-ketoesters represented by the following general formula (XII):
R⁹COCR¹⁰HCOR¹¹ (XII)
where R⁹ is a saturated or unsaturated hydrocarbon group having 1-6 carbon atoms; R¹⁰ is H or CH₃; and R¹¹ is an alkyl or alkoxyl group having 1-6 carbon atoms.

Specific examples of the β-diketones that can be used in the invention include acetylacetone, 3-methyl-2,4-pentanedione and benzoylacetone. Exemplary β-ketoesters include ethyl acetoacetate and diethyl malonate. Other complex formers may of course be employed, however, complex formers, such as hexafluoroacetylacetone, that form metal halides after baking are not suitable for use in the coating solutions of the invention since they form highly sublimable or volatile metal complexes.

Regarding glycols as the stabilizer, at least one compound is preferably used as selected from among the glycols represented by the following general formula (XIII):
HOR¹²OH (XIII)
where R¹² is a divalent saturated or unsaturated hydrocarbon group having 1-6 carbon atoms.

Specific examples of the glycols that can be used in the invention include 1,2-ethanediol, 1,3-propanediol, 1,2-propanediol, 2,3-butanediol, diethylene glycol, 1,5-pentanediol, 2,2-dimethyl-1,3-propanediol, 1,4-cyclohexanediol, dipropylene glycol, 2,2-diethyl-1,3-propanediol, 2,5-dimethyl-2,5-hexanediol, 2-ethyl-1,3-hexanediol and tetraethylene glycol.

The stabilizers listed above are preferably of a short-chain type having 1-6 carbon atoms in order to enhance the polarity of the metallic compounds and the inorganicity of the as-applied coatings.

If desired, lower monocarboxylic acids, such as acetic acid, propionic acid, butyric acid and valeric acid, may also be used as the stabilizer.

Turning back to the case where the coating solutions for use in forming Bi-based ferroelectric thin films are subjected to hydrolysis and partial polycondensation, the reaction is performed by adding water, either alone or in combination with a catalyst, into the coating solution and stirring the mixture at 20-50° C. for several hours to several days. The catalyst may be of any known type suitable for use in the reaction of hydrolysis of metal alkoxides and examples include acid catalysts which may be inorganic acids (e.g., hydrochloric acid, sulfuric acid and nitric acid) or organic acids (e.g., acetic acid, propionic acid and butyric acid), and inorganic or organic alkali catalysts such as sodium hydroxide, potassium hydroxide, ammonia, monoethanolamine, diethanolamine and tetramethylammonium hydroxide. From the viewpoint of providing good characteristics for applied coats, the use of acid catalysts is particularly preferred.

By thusly performing various treatments such as carboxylation, conversion to β-diketone forms and chelation through the reaction of composite metal alkoxides with stabilizers, the synthesis of polar and highly stable products can successfully be accomplished with improved hydrolyzability and higher solubility in practical polar solvents. As a result, the polycondensation reaction can be allowed to proceed in the coating solution through sol-gel processing by a sufficient degree that inorganic bonds (methaloxane bonds) such as Bi—O—Bi, Bi—O—Ta, Bi—O—Sr and Ta—O—Bi—O—Sr are generated; this contributes not only to reducing the precipitation (segregation) of specific metal elements such as Bi and suppressing the loss of organic content due to burning but also to enhancing the inorganicity of the coating solution taken as a whole.

In the thin film forming method of the invention, the coating solution described above is applied to a substrate, dried and subjected to a rapid heat treatment at a temperature rise rate of at least 10° C./s, preferably at least 50° C./s, to form a Bi-based ferroelectric thin film.

The substrate that can be used is in no way limited and may be exemplified by semiconductor substrates such as silicon substrates and glass substrates. Also useful are substrates that have electrode materials for ferroelectric memories formed either on the SiO₂ film formed by oxidizing the top of a silicon wafer or on the assembly of an insulation layer, first-level conductor, interlevel dielectric layer, etc. Electrode materials can be formed by any known techniques such as sputtering and evaporation and the thickness of their film is not limited to any particular value. Any conductive materials may be used as electrode materials and their examples include metals such as Pt, Ir, Ru, Re and Os, as well as their conductive oxides.

The coating solutions for use in forming Bi-based ferroelectric thin films can be applied by any known coating methods such as LSMCD (liquid source misted chemical deposition), spinning and dipping.

The drying step may typically be performed in nitrogen, air atmosphere or oxygen atmosphere. The drying time varies with the drying temperature and is not limited to any particular value, except that the coating on the substrate should not be free-flowing to vary in thickness or spill off the substrate as it is transported on the conveyor line. The drying means also is not limited in any particular way, to give just one example, the substrate having the coating on it is placed on a temperature-controlled hot plate.

The next step is a heat treatment for burning away the organic components in the coating to form a metal oxide film. While there is no particular limitation on the heating means that can be employed, rapid thermal annealing (RTA) with a hot plate, an anneal lamp or the like is particularly suitable for the coating solution of the invention since its organic components have low enough decomposition temperatures to achieve rapid conversion to inorganic nature and because only small weight loss occurs upon decomposition of the organic components. Even if the coat formed by application of the coating solution of the invention is subjected to rapid heat treatment such as RTA, the organic components of the coat are sufficiently decomposed to form a highly crystalline film. In other words, the coating solution of the invention has the advantage of forming a film characterized by full crystallization from the fluorite to perovskite structure. This can be verified by XRD analysis of the film which gives a curve showing negligible broad peaks for the fluorite structure at about 2θ=33° and 48° while presenting a large sharp peak for the perovskite structure at about 2θ=29°.

The heat treatment may typically be performed in an inert gas (e.g., nitrogen), air atmosphere or oxygen atmosphere and the selection of a suitable atmosphere depends on the object.

The applied coating may also be heated by slowly raising the temperature in a furnace. In this slow heat treatment, the coating solution that has been subjected to hydrolysis or treated by addition of stabilizers as described above is preferably used in order to form a film having better surface homology.

The film formed by application of the stabilized coating solution has particular advantages of being dense and exhibiting good electrical characteristics.

While there is no particular limitation on the thickness of the ferroelectric thin film to be formed, a plurality of layers each having a thickness or about 20-100 nm may be formed one on top of another to give a final thickness of about 80-300 nm by repeating the process of application, drying and heating several times (usually 2-5 times) and this is preferred for the purpose of providing good electrical characteristics.

The following examples are provided for the purpose of further illustrating the present invention but are in no way to be taken as limiting.

### EXAMPLES

Synthesis 1 (Compositing→Hydrolysis→Adding Specified Compound)

To stirred 2-methoxypropanol (700 g), Sr isopropoxide (0.08 moles), Ta ethoxide (0.20 moles) and Bi butoxide (0.22 moles) were successively added at room temperature (25° C.), with the stirring continued until a uniform solution formed.

Subsequently, the solution was heated up to 60° C. and stirred for 7 hours at the same temperature.

Thereafter, the heating was ceased and the solution was stirred until it cooled down to room temperature; then, water (0.2 moles) was added in small portions and after the end of its addition, the solution was stirred for 2 hours to form a composite metal alkoxide solution (solution A).

Subsequently, solution A was agitated vigorously as tetraglyme (0.45 moles, corresponding to 4.45 molar equivalents if the total valence of metallic elements is calculated as 18) was added; thereafter, the mixture was heated up to 50° C. and stirred for 3 hours at the same temperature.

Subsequently, the mixture was diluted with 2-methoxypropanol to prepare coating solution 1 having a concentration of 10 wt % as calculated for strontium bismuth tantalum oxide.

Synthesis 2

Coating solution 2 was prepared by repeating Synthesis 1, except that tetraglyme (0.45 moles) was replaced by triglyme (0.45 moles).

Synthesis 3

Coating solution 3 was prepared by repeating Synthesis 1, except that tetraglyme (0.45 moles) was replaced by pinacol (0.45 moles).

Synthesis 4

Coating solution 4 was prepared by repeating Synthesis 1, except that tetraglyme (0.45 moles) was replaced by pivalic acid (0.45 moles).

Synthesis 5

Coating solution 5 was prepared by repeating Synthesis 1, except that tetraglyme (0.45 moles) was replaced by dipivaloylmethane (0.45 moles).

Synthesis 6

Coating solution 6 was prepared by repeating Synthesis 5, except that the amount of addition of dipivaloylmethane was decreased from 0.45 moles to 0.30 moles (corresponding to 2.97 molar equivalents if the total valence of metallic elements is calculated as 18).

Synthesis 7

Coating solution 7 was prepared by repeating Synthesis 5, except that the amount of addition of dipivaloylmethane was decreased from 0.45 moles to 0.15 moles (corresponding to 1.48 molar equivalents if the total valence of metallic elements is calculated as 18).

Synthesis 8

Coating solution 8 was prepared by repeating Synthesis 5, except that the amount of addition of dipivaloylmethane was decreased from 0.45 moles to 0.09 moles (corresponding to 0.89 molar equivalents if the total valence of metallic elements is calculated as 18).

Synthesis 9

Coating solution 9 was prepared by repeating Synthesis 1, except that tetraglyme (0.45 moles) was replaced by hexylene glycol (i.e., 2-methyl-2,4-pentanediol, 0.45 moles).

Comparative Synthesis 1 (Compositing→Hydrolysis, Specified Compound Not Added)

Solution A was prepared by repeating the method described in Synthesis 1.

Subsequently, the solution was diluted with 2-methoxypropanol to prepare comparative coating solution 1 having a concentration of 10 wt % as calculated for strontium bismuth tantalum oxide.

Comparative Synthesis 2 (Compositing→Hydrolysis→Adding 2-Ethylhexanoic Acid)

Comparative coating solution 2 was prepared by repeating Synthesis 1, except that tetraglyme (0.45 moles) was replaced by 2-ethylhexanoic acid (0.45 moles).

Comparative Synthesis 3 (Compositing→Hydrolysis→Adding Ethyl Acetoacetate)

Comparative coating solution 3 was prepared by repeating Synthesis 1, except that tetraglyme (0.45 moles) was replaced by ethyl acetoacetate (0.45 moles).

Comparative Synthesis 4 (Compositing→Hydrolysis→Adding Acetylacetone)

Comparative coating solution 4 was prepared by repeating Synthesis 1, except that tetraglyme (0.45 moles) was replaced by acetylacetone (0.45 moles).

Comparative Synthesis 5 (Compositing→Hydrolysis→Adding Propylene Glycol)

Comparative coating solution 5 was prepared by repeating Synthesis 1, except that tetraglyme (0.45 moles) was replaced by propylene glycol (0.45 moles).

Synthesis 10 (Compositing→Adding Specified Compound)

To stirred 2-methoxypropanol (700 g), Sr isopropoxide (0.08 moles), Ta ethoxide (0.20 moles) and Bi butoxide (0.22 moles) were successively added at room temperature (25° C.), with the stirring continued until a uniform solution formed.

Subsequently, the solution was heated up to 60° C. and stirred for 7 hours at the same temperature. Thereafter, the heating was ceased and the solution was stirred until it cooled down to room temperature.

Subsequently, the solution was agitated vigorously as tetraglyme (0.45 moles, corresponding to 4.45 molar equivalents if the total valence of metallic elements is calculated as 18) was added; thereafter, the mixture was heated up to 50° C. and stirred for 3 hours at the same temperature.

Subsequently, the mixture was diluted with 2-methoxypropanol to prepare coating solution 10 having a concentration of 10 wt % as calculated for strontium bismuth tantalum oxide.

Synthesis 11 (Compositing→Hydrolysis→Adding Specified Compound)

To stirred 2-methoxypropanol (700 g), La acetate (0.075 moles), Ti isopropoxide (0.30 moles) and Bi butoxide (0.325 moles) were successively added at room temperature, with the stirring continued until a uniform solution formed.

Subsequently, the solution was heated up to 80° C. and stirred for 2 hours at the same temperature.

Thereafter, the heating was ceased and the solution was stirred until it cooled down to room temperature; then, water (0.2 moles) was added in small portions and after the end of its addition, the solution was stirred for 2 hours to form a composite metal alkoxide solution (solution B).

Subsequently, solution B was agitated vigorously as tetraglyme (0.45 moles, corresponding to 4.5 molar equivalents if the total valence of metallic elements is calculated as 24) was added;

thereafter, the mixture was heated up to 50° C. and stirred for 3 hours at the same temperature.

Subsequently, the mixture was diluted with 2-methoxypropanol to prepare coating solution 11 having a concentration of 10 wt % as calculated for lanthanum bismuth titanium oxide.

Comparative Synthesis 6 (Compositing→Hydrolysis, Specified Compound Not Added)

Solution B was prepared by repeating the method described in Synthesis 11. Subsequently, the solution was diluted with 2-methoxypropanol to prepare comparative coating solution 6 having a concentration of 10 wt % as calculated for lanthanum bismuth titanium oxide.

Synthesis 12 (Compositing→Hydrolysis→Adding Specified Compound+Stabilizer)

Solution A was prepared by repeating the method described in Synthesis 1. Subsequently, solution A was agitated vigorously as hexylene glycol (0.45 moles, corresponding to 4.45 molar equivalents if the total valence of metallic elements is calculated as 18) and ethyl acetoacetate (3 moles as stabilizer) were added; thereafter, the mixture was heated up to 50° C. and stirred for 3 hours at the same temperature.

Subsequently, the mixture was diluted with 2-methoxypropanol to prepare coating solution 12 having a concentration of 10 wt % as calculated for strontium bismuth tantalum oxide.

Synthesis 13

Coating solution 13 having a concentration of 10 wt % as calculated for strontium bismuth tantalum oxide was prepared by repeating Synthesis 12, except that ethyl acetoacetate was replaced by 1,2-dipropanediol.

Synthesis 14

Coating solution 14 having a concentration of 10 wt % as calculated for strontium bismuth tantalum oxide was prepared by repeating Synthesis 12, except that ethyl acetoacetate was replaced by 2,2-dimethyl-1,3-propanediol.

Synthesis 15

Coating solution 15 having a concentration of 10 wt % as calculated for strontium bismuth tantalum oxide was prepared by repeating Synthesis 12, except that ethyl acetoacetate was replaced by 2,5-dimethyl-2,5-hexanediol.

Synthesis 16

Coating solution 16 having a concentration of 10 wt % as calculated for strontium bismuth tantalum oxide was prepared by repeating Synthesis 12, except that ethyl acetoacetate was replaced by n-butyric acid.

### Example 1

### Evaluation of TG Curves

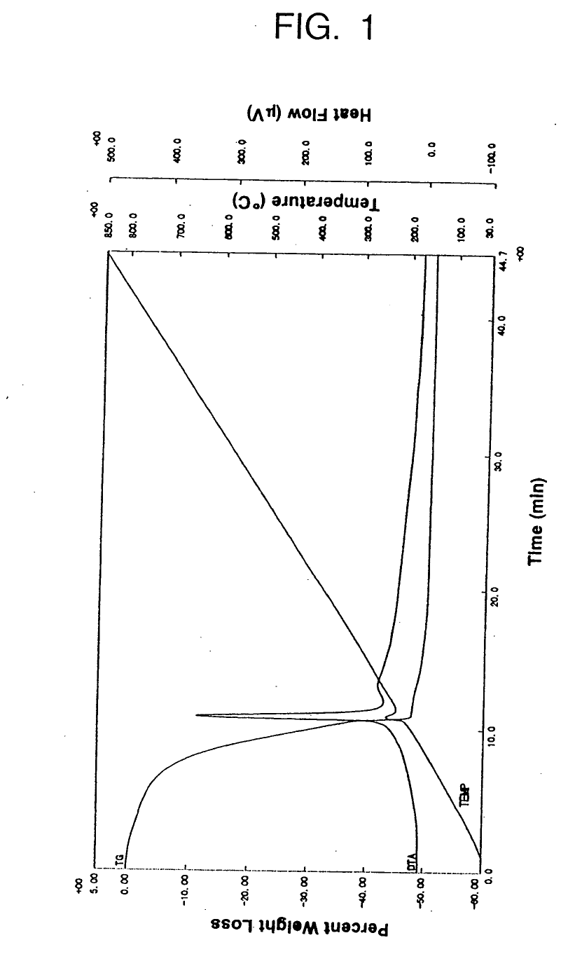

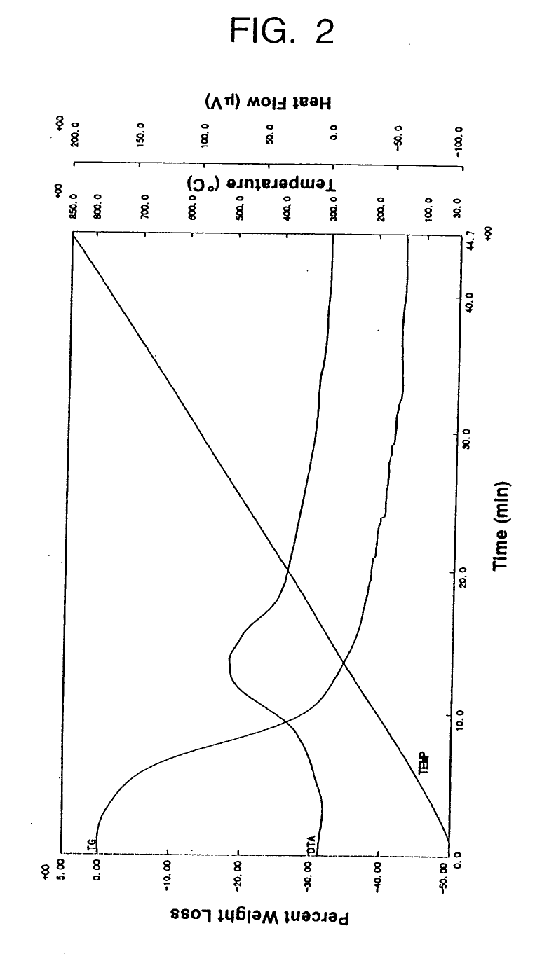

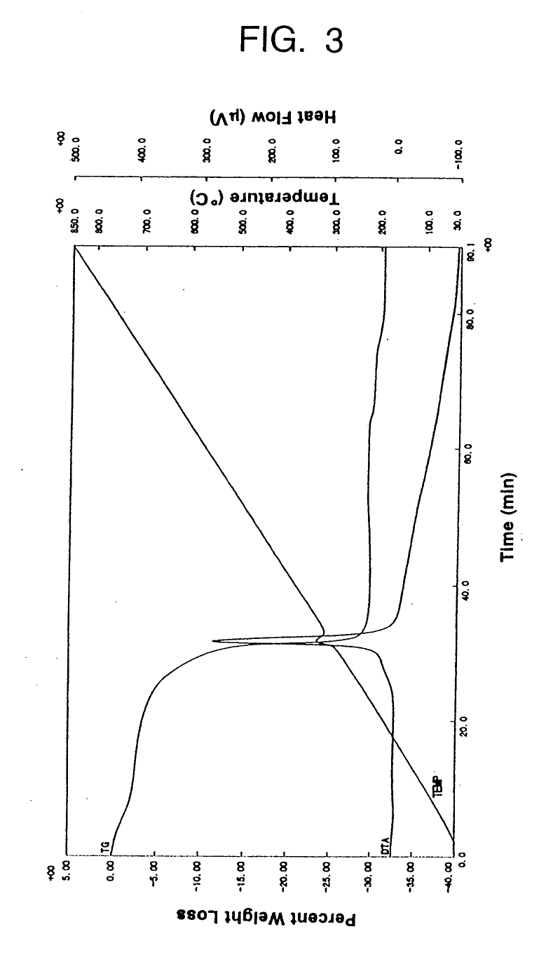

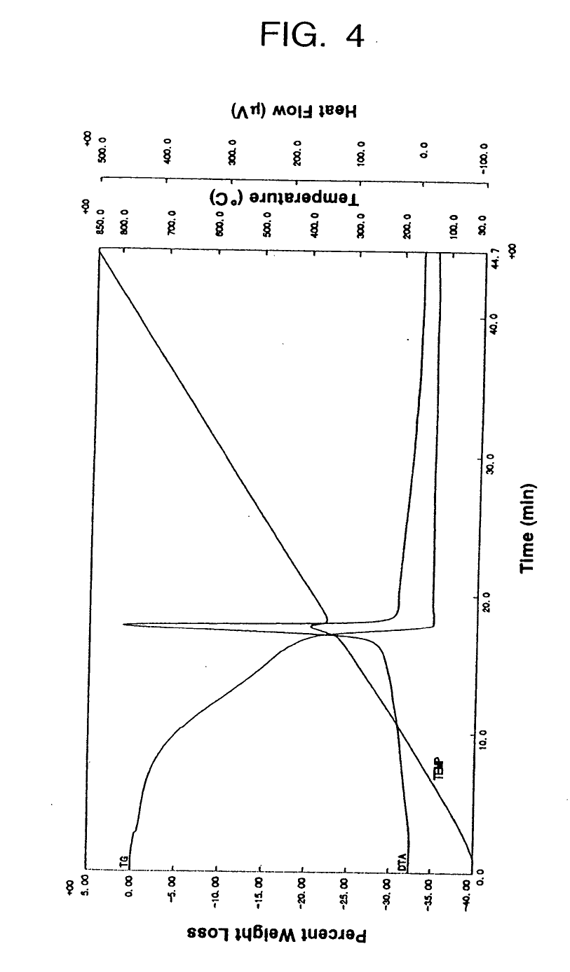

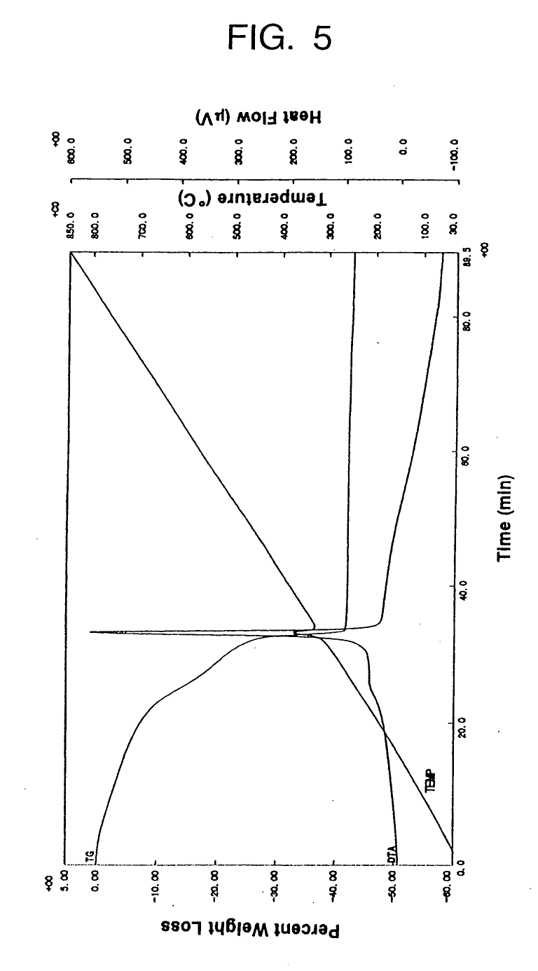

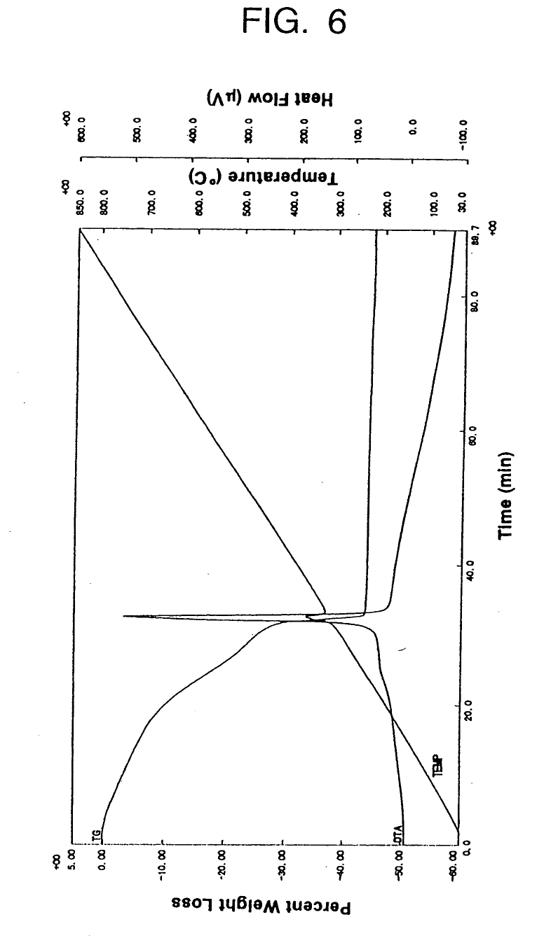

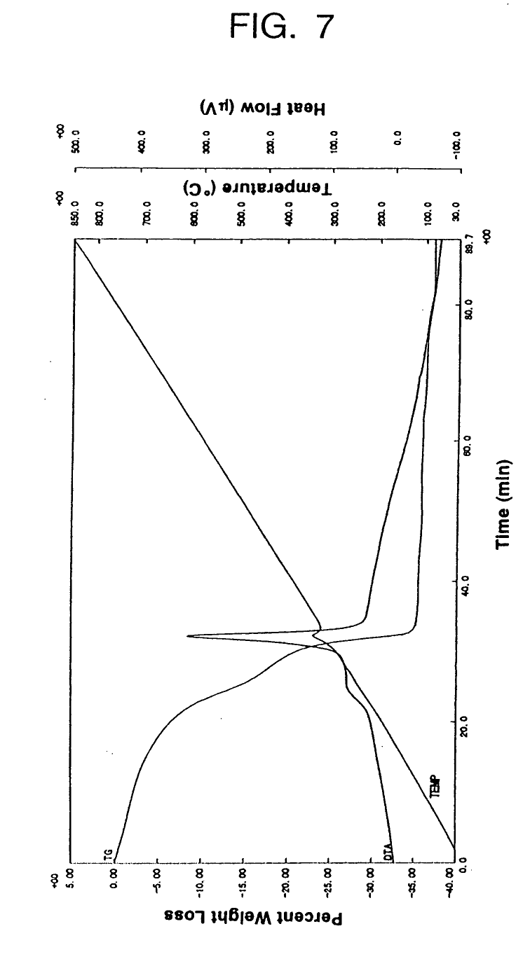

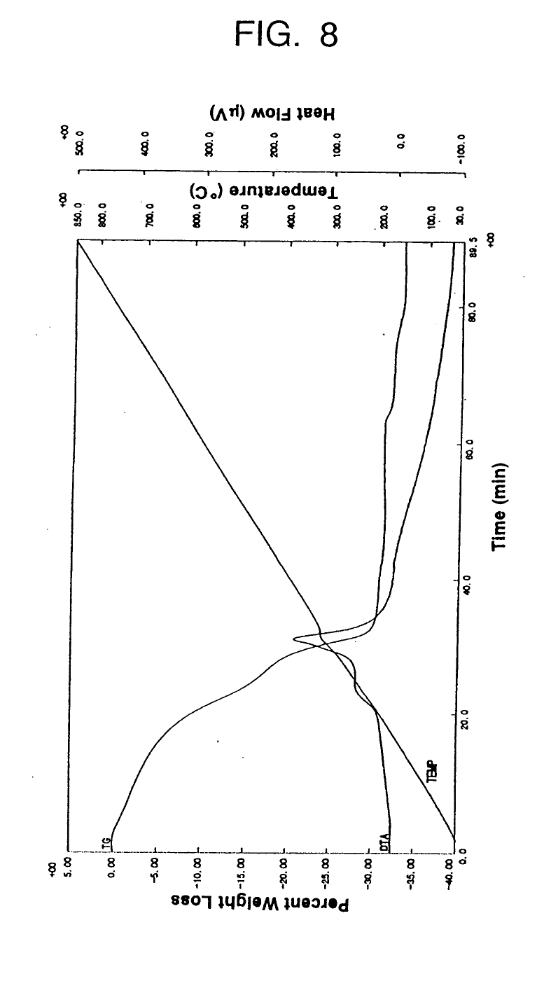

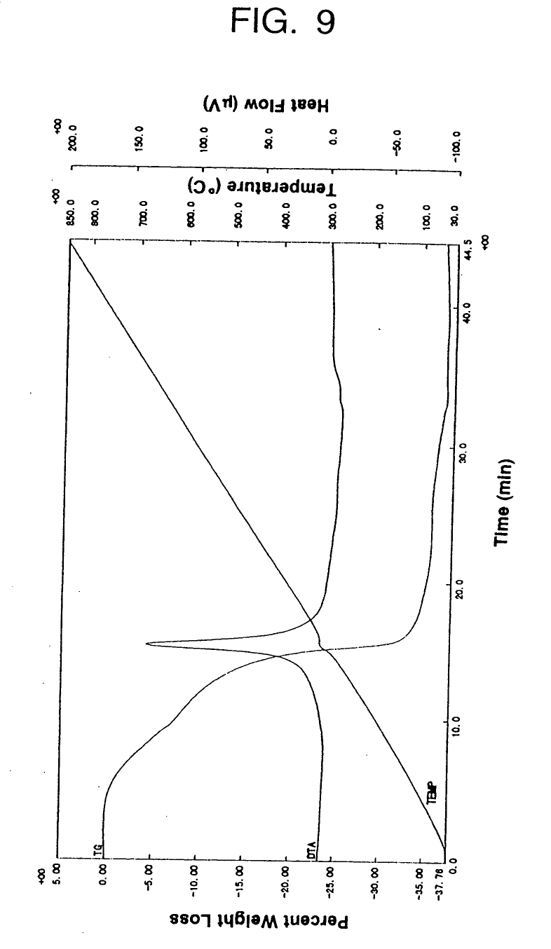

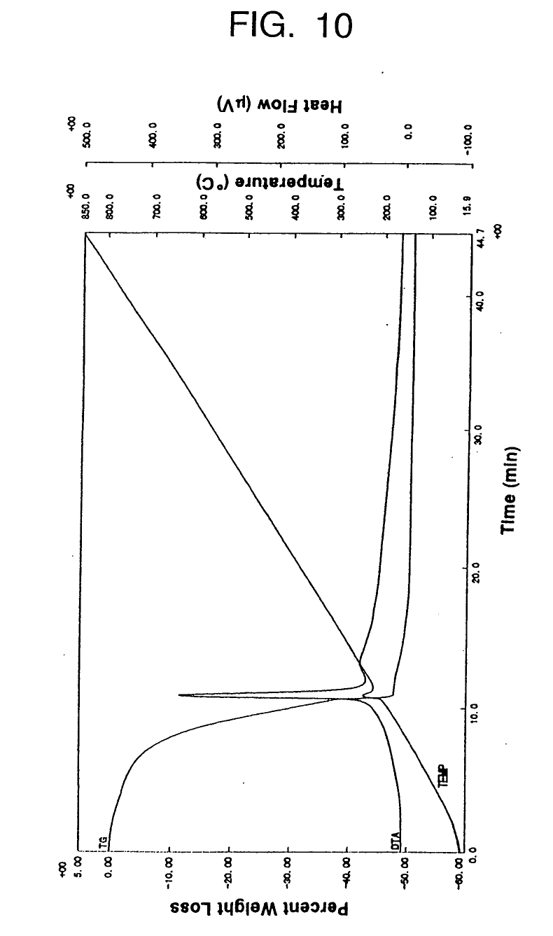

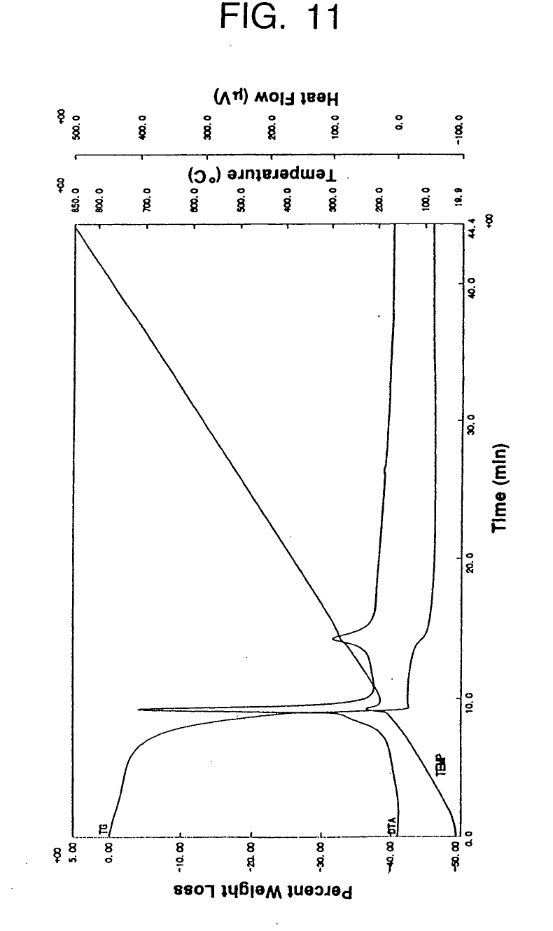

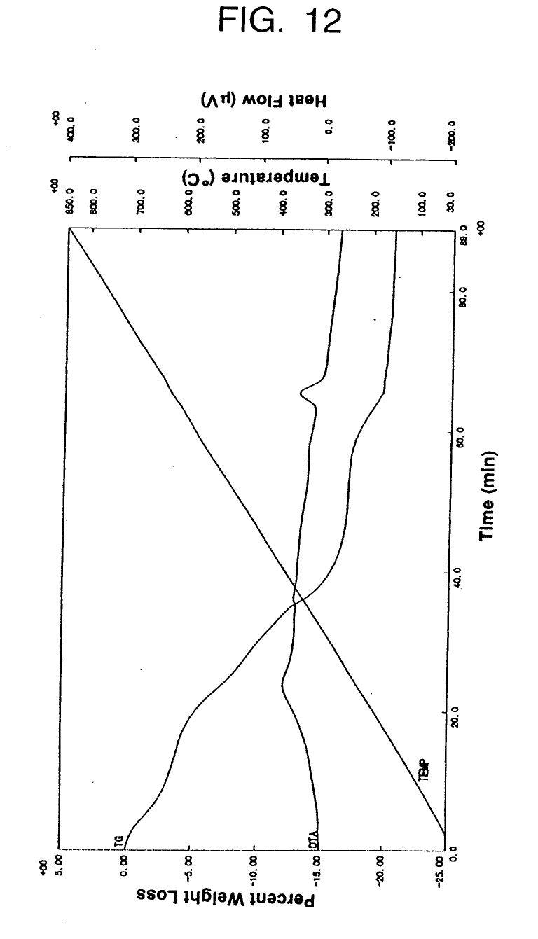

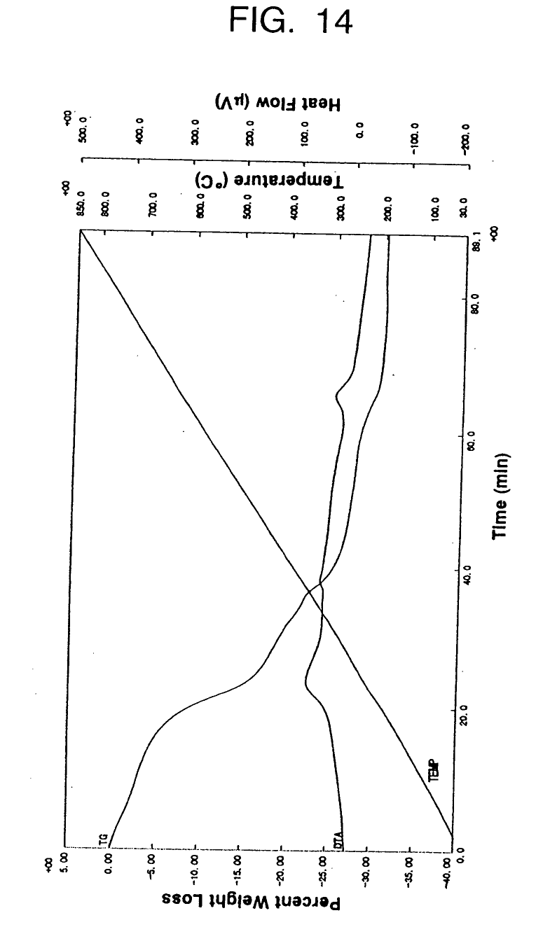

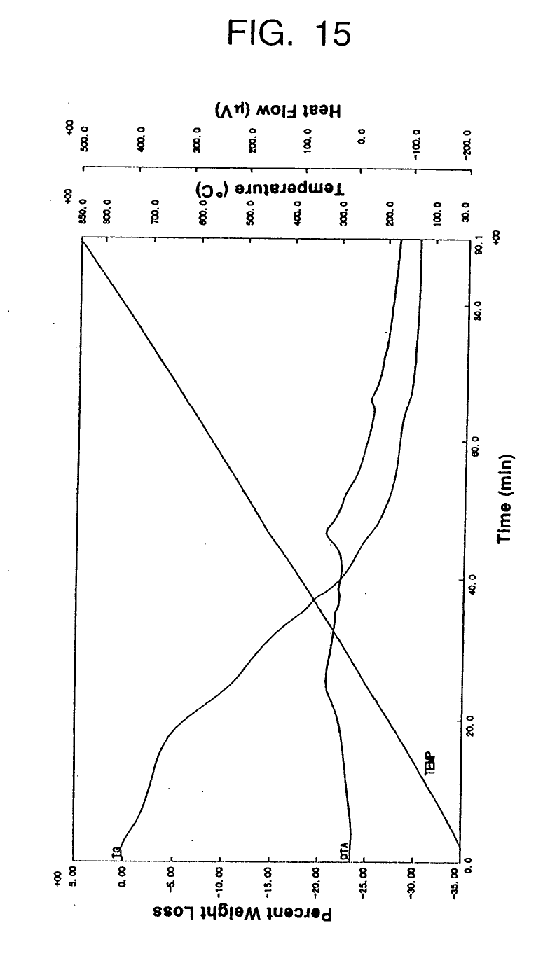

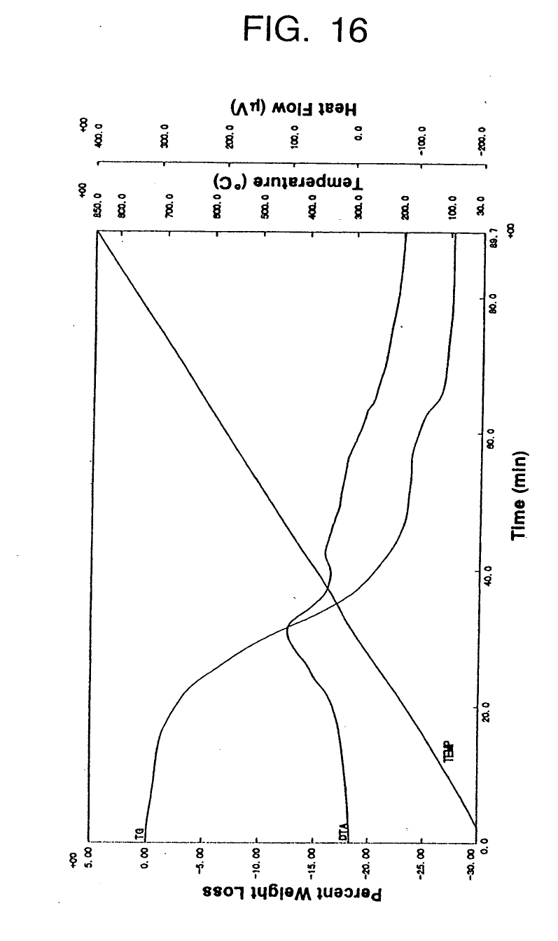

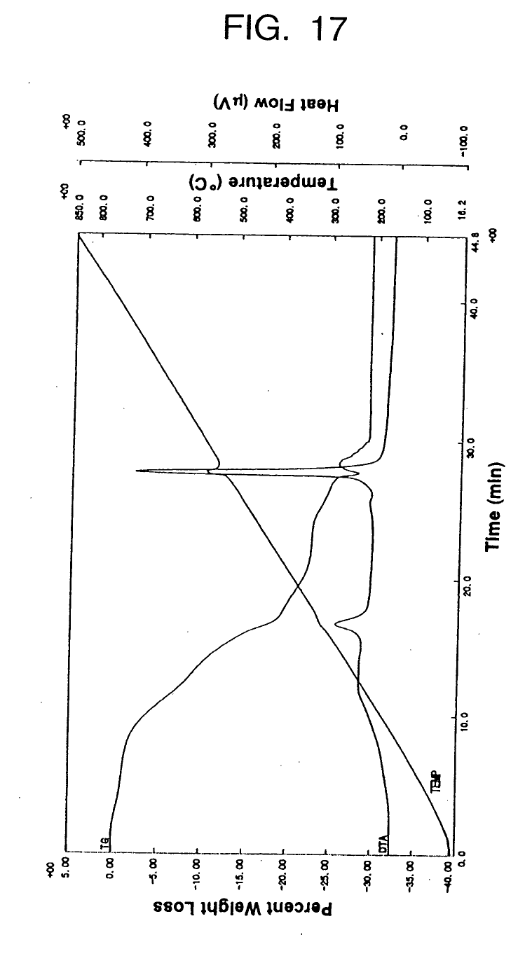

The coating solutions prepared in Syntheses 1-11 and Comparative Syntheses 1-6 were heated at a rate of 20° C./min to remove the solvent; after cooling down to 20° C., the coating solutions were again heated at a rate of 20° C./min to determine TG (thermogravimetric) curves. The TG curves for coating solutions 1-11 are shown in FIGS. 1-11 and those for comparative coating solutions 1-6 are shown in FIGS. 12-17. In FIGS. 1-17, curves labelled TEMP show the temperature (° C.) of the as-applied coat.

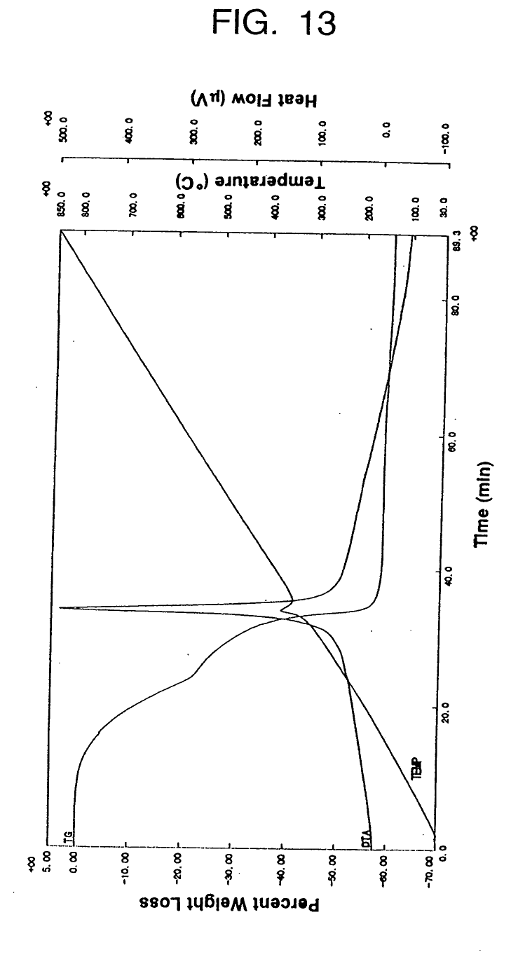

By comparing FIGS. 1-11 with FIGS. 12-17, one can see that coating solutions 1-11 had low enough decomposition temperatures for the organic components that they were converted to inorganic nature within short periods whereas they lost weight by only about 25-45% after decomposition of the organic components. It is clear from FIG. 13 that comparative coating solution 2 using 2-ethylhexanoic acid suffered a significant weight loss of about 60%.

### Example 2

### Evaluation of XRD Analyses

The coating solutions prepared in Syntheses 1-3, 5 and 9 were whirl coated on silicon wafers with a spinner and dried at 80° C. for 3 minutes to form dry coats 60 nm thick. The same procedure was further repeated twice to form dry coats 180 nm thick.

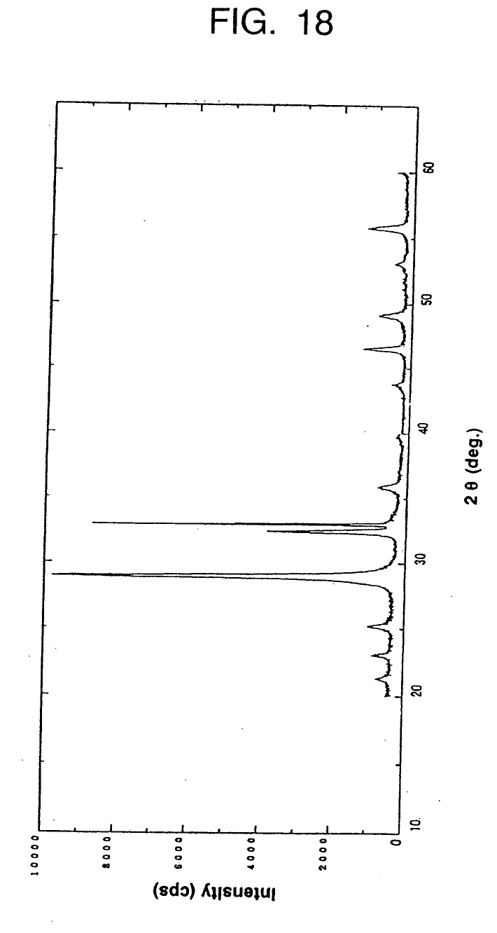

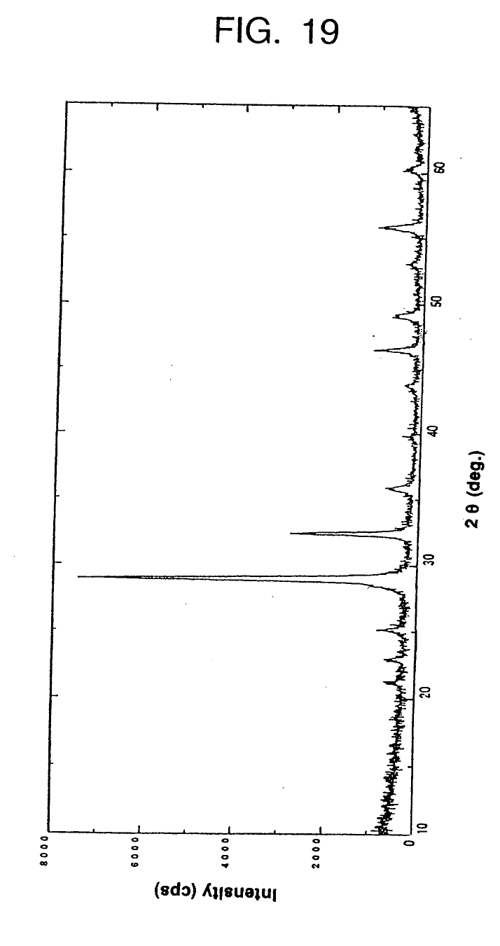

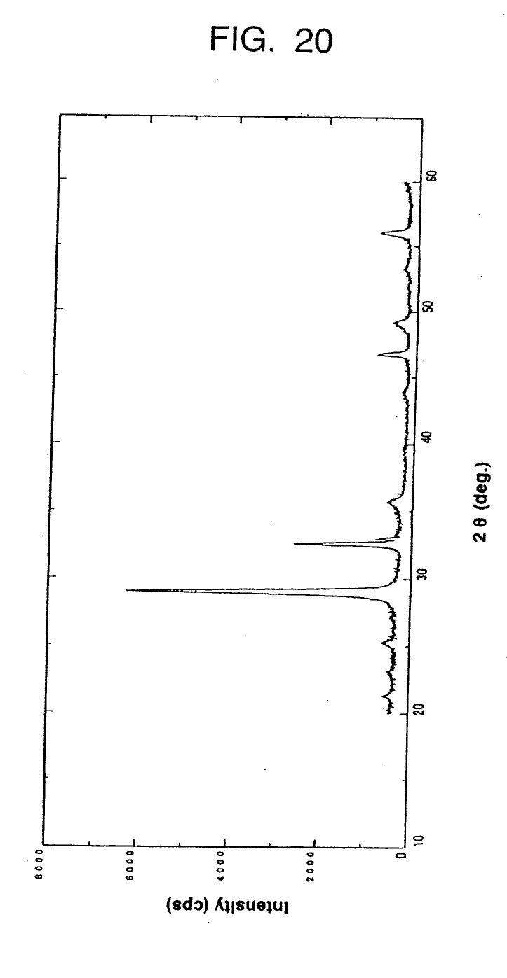

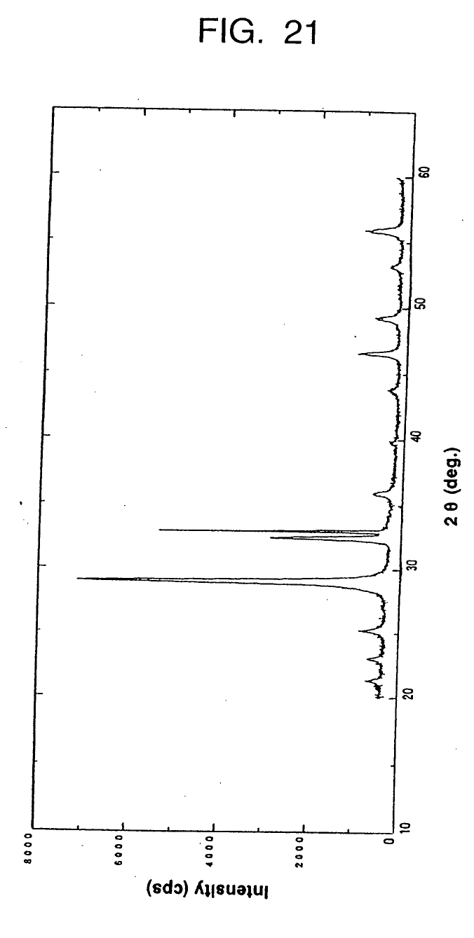

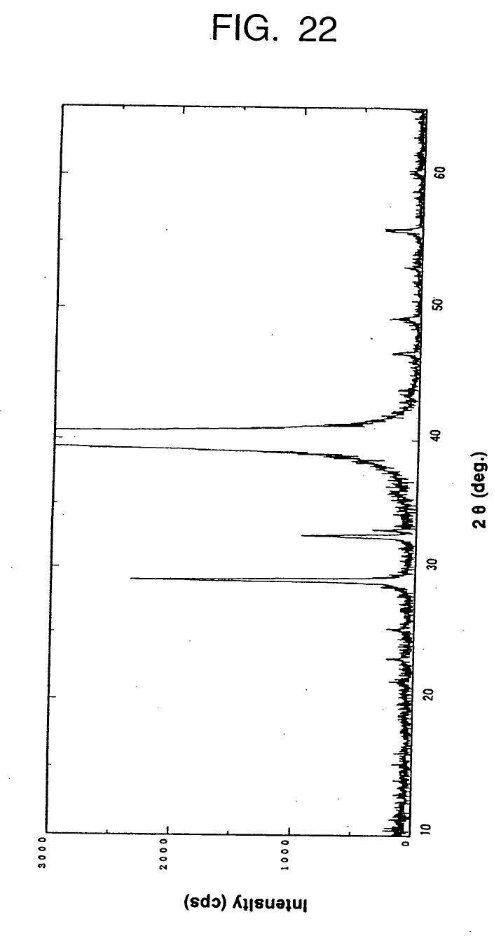

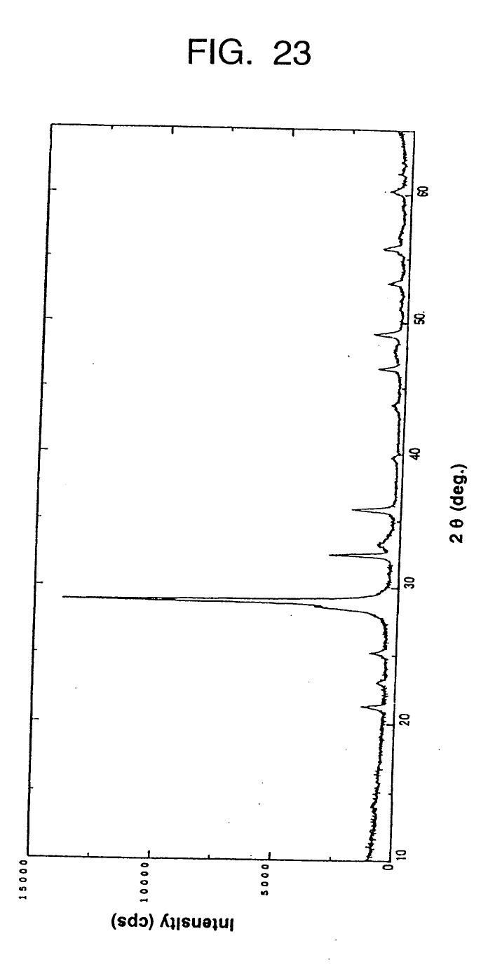

The coatings were heated up to 700° C. at a rate of 100° C./s and heat treated at the same temperature for 1 minute to form Bi-based ferroelectric thin films. The XRD curves for coating solutions 1-3, 5 and 9 are shown in FIGS. 18-22, respectively, and the XRD curve for comparative coating solution 1 is shown in FIG. 23.

Judging from the peak intensities for 20 values of about 29°, 33° and 48° in FIGS. 18-23, the ferroelectric films formed from coating solutions 1-3, 5 and 9 had good crystallinity in the substantial absence of the fluorite structure whereas the ferroelectric film formed from comparative coating solution 1 had only poor crystallinity since it partly included the fluorite structure.

### Example 3

### Evaluation of Film Quality by SEM

The coating solutions prepared in Synthesis 1 and Comparative Synthesis 1 were whirl coated on silicon wafers with a spinner and dried at 50° C. for 5 minutes, then heated at 500° C. for 30 minutes to form dry coats 60 nm thick.

The same procedure was further repeated twice, and then a heat treatment was performed at 750° C. for 60 minutes to form Bi-based ferroelectric thin films 180 nm thick.

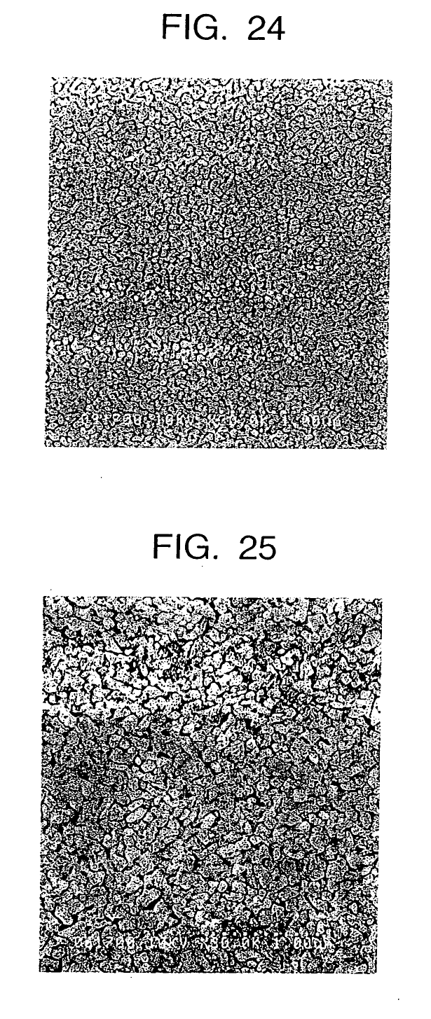

A SEM of the ferroelectric thin film formed from coating solution 1 is shown in FIG. 24, and a SEM of the ferroelectric thin film formed from comparative coating solution 1 is shown in FIG. 25. As is clear from comparison between FIGS. 24 and 25, the ferroelectric thin film formed from coating solution 1 had high quality since it consisted of fine crystal grains that produced a dense structure with a limited number of voids.

### Example 4

### Evaluation of Film Quality by Refractometer

The coating solutions prepared in Syntheses 9 and 12-16 were whirl coated on silicon wafers with a spinner and dried at 50° C. for 5 minutes, then heated at 500° C. for 30 minutes, finally at 750° C. for 60 minutes to form Bi-based ferroelectric thin films 40 nm thick.

The refractive index of each of these thin films was measured actometer (automatic ellipsometer Model DVA-36L of aku Kogyosho). The results are shown in Table 1.

TABLE 1

| Coating | | |
|---|---|---|
| solution | | Refractive |
| No. | Additives | index (N) |
| 9 | hexylene glycol | 2.06 |
| 12 | hexylene glycol; ethyl acetoacetate | 2.14 |
| 13 | hexylene glycol; 1,2-propanediol | 2.15 |
| 14 | hexylene glycol; 2,2-dimethyl-1,3-propanediol | 2.21 |
| 15 | hexylene glycol; 2,5-dimethyl-2,5-hexanediol | 2.16 |
| 16 | hexylene glycol; n-butyric acid | 2.18 |

As is clear from Table 1, compared with coating solution 9 using hexylene glycol alone, coating solutions 12-16 using hexylene glycol in combination with stabilizers could form films of high refractive indices reflecting their increased denseness.

The same result was observed for electrical characteristics and compared with coating solution 9 using hexylene glycol alone, coating solutions 12-16 using hexylene glycol in combination with stabilizers had higher Pr values (polarizability).

As described above in detail, the present invention provides a coating solution for use in forming Bi-based ferroelectric thin films, and a method of forming Bi-based ferroelectric thin films using the coating solution, whereby to achieve advantages that may include one or two of the following: permitting organic components to be decomposed at low enough temperature, forming a coat that permits rapid conversion to inorganic nature, and forming a coat that loses only small weight after decomposition of organic components.

1. A coating solution for use in forming Bi-based ferroelectric thin films that comprises an organometallic compound containing the metallic elements of which a Bi-based ferroelectric thin film is composed, and a compound represented by the following general formula (I):
H₃CO—(C₂H₄O)ₙ—CH₃ (I)
where n is an integer of 2-5,
wherein said organometallic compound comprises a Bi alkoxide, a metal A alkoxide, where A is at least one metallic element selected from among Bi, Pb, Ba, Sr, Ca, Na, K and a rare earth metallic element, and a metal B alkoxide, where B is at least one metallic element selected from among Ti, Nb, Ta, W, Mo, Fe, Co and Cr, as well as at least two dissimilar metal alkoxides selected from among the metal A alkoxide, metal B alkoxide and Bi alkoxide form a composite metal alkoxide.

2. The coating solution for use in forming Bi-based ferroelectric thin films according to claim 1, wherein said organometallic compound and the compound represented by said general formula (I) (where n is as defined in claim 1) have reacted with each other to form a reaction product.

3. The coating solution for use in forming Bi-based ferroelectric thin films according to claim 1, which is stabilized with at least one stabilizer selected from among carboxylic anhydrides, dicarboxylic acid monoesters, β-diketones and glycols.

4. A coating solution for use in forming Bi-based ferroelectric thin films that comprises an organometallic compound containing the metallic elements of which a Bi-based ferroelectric thin film is composed, and a compound represented by the following general formula (II):
(R¹)₃C—CO—CH₂—CO—C(R¹)₃ (II)
where R¹ is an alkyl group having 1-3 carbon atoms.

5. The coating solution for use in forming Bi-based ferroelectric thin films according to claim 4, wherein said organometallic compound and the compound represented by said general formula (II) (where R¹ is as defined in claim 4) have reacted with each other to form a reaction product.

6. The coating solution for use in forming Bi-based ferroelectric thin films according to claim 4, which is stabilized with at least one stabilizer selected from among carboxylic anhydrides, dicarboxylic acid monoesters, β-diketones and glycols.

7. A coating solution for use in forming Bi-based ferroelectric thin films that comprises an organometallic compound containing the metallic elements of which a Bi-based ferroelectric thin film is composed, and a compound represented by the following general formula (III):
(R¹)₂C(OH)—C(OH)(R¹)₂ (III)
where R¹ is an alkyl group having 1-3 carbon atoms.

8. The coating solution for use in forming Bi-based ferroelectric thin films according to claim 7, wherein said organometallic compound and the compound represented by said general formula (III) (where R¹ is as defined in claim 7) have reacted with each other to form a reaction product.

9. The coating solution for use in forming Bi-based ferroelectric thin films according to claim 7, which is stabilized with at least one stabilizer selected from among carboxylic anhydrides, dicarboxylic acid monoesters, β-diketones and glycols.

10. A coating solution for use in forming Bi-based ferroelectric thin films that comprises an organometallic compound containing the metallic elements of which a Bi-based ferroelectric thin film is composed, and a compound represented by the following general formula (IV):
(R¹)₃C—COOH (IV)
where R¹ is an alkyl group having 1-3 carbon atoms.

11. The coating solution for use in forming Bi-based ferroelectric thin films according to claim 10, wherein said organometallic compound and the compound represented by said general formula (IV) (where R¹ is as defined in claim 10) have reacted with each other to form a reaction product.

12. The coating solution for use in forming Bi-based ferroelectric thin films according to claim 10, which is stabilized with at least one stabilizer selected from among carboxylic anhydrides, dicarboxylic acid monoesters, β-diketones and glycols.

13. A coating solution for use in forming Bi-based ferroelectric thin films that comprises an organometallic compound containing the metallic elements of which a Bi-based ferroelectric thin film is composed, and a compound represented by the following general formula (V):
(R¹)₂C(OH)—CH₂—CH(OH)R¹ (V)
where R¹ is an alkyl group having 1-3 carbon atoms.

14. The coating solution for use in forming Bi-based ferroelectric thin films according to claim 13, wherein said organometallic compound and the compound represented by said general formula (V) (where R¹ is as defined in claim 13) have reacted with each other to form a reaction product.

15. The coating solution for use in forming Bi-based ferroelectric thin films according to claim 13, which is stabilized with at least one stabilizer selected from among carboxylic anhydrides, dicarboxylic acid monoesters, β-diketones and glycols.

16. The coating solution for use in forming Bi-based ferroelectric thin films according to any one of claims 1, 4, 7, 10 and 13, wherein said organometallic compound comprises a Bi alkoxide, a metal A alkoxide, where A is at least one metallic element selected from among Bi, Pb, Ba, Sr, Ca, Na, K and a rare earth metallic element, and a metal B alkoxide, where B is at least one metallic element selected from among Ti, Nb, Ta, W, Mo, Fe, Co and Cr.

17. (canceled)

18. The coating solution for use in forming Bi-based ferroelectric thin films according to any one of claims 1, 4, 7, 10 and 13, which is intended to form thin films containing Bi-layered structure compounds represented by the following general formula (VI):
(Bi₂O₂)²⁺(Aₘ₋₁BₘO₃ₘ₊₁)²⁻ (VI)
where A is at least one metallic element selected from among Bi, Pb, Ba, Sr, Ca, Na, K and a rare earth metallic element; B is at least one metallic element selected from among Ti, Nb, Ta, W, Mo, Fe, Co and Cr; and m is an integer of 1-5.

19. The coating solution for use in forming Bi-based ferroelectric thin films according to any one of claims 1, 4, 7, 10 and 13, which is intended to form thin films containing Bi-layered structure compounds represented by the following general formula (VII):
Sr₁₋ₓBi_{2+y}(Ta_{2-z},Nb_{z})O_{9+α} (VII)
where 0≦x, y and α, independently <1; and 0≦z<2.

20. The coating solution for use in forming Bi-based ferroelectric thin films according to any one of claims 1, 4, 7, 10 and 13, which is intended to form thin films containing Bi-layered structure compounds represented by the following general formula (VIII):
La₁₋ₓBi_{4-y}Ti₃O_{12+α} (VIII)
where 0≦x, y and α, independently <1.

21. The coating solution for use in forming Bi-based ferroelectric thin films according to any one of claims 1, 4, 7, 10 and 13, which was converted to a sol-gel fluid by hydrolysis and partial polycondensation using water either alone or in combination with a catalyst.

22. A method of forming Bi-based ferroelectric thin films which comprises applying one of the coating solutions of claim 1 onto a substrate, drying the applied coating solution, and then performing a rapid heat treatment at a temperature rise rate of at least 10° C./s to form a Bi-based ferroelectric thin film.
